(19) United States
(12) Patent Application Publication
(10) Pub. No.: US 2025/0344395 A1
(43) Pub. Date: Nov. 6, 2025

(54) NOR FLASH MEMORY AND MANUFACTURING METHOD THEREOF

(71) Applicant: Winbond Electronics Corp., Taichung City (TW)

(72) Inventor: Riichiro Shirota, Taichung City (TW)

(73) Assignee: Winbond Electronics Corp., Taichung City (TW)

(21) Appl. No.: 19/070,524

(22) Filed: Mar. 5, 2025

(30) Foreign Application Priority Data
May 1, 2024 (JP) 2024-074328
May 13, 2024 (JP) 2024-077743
Aug. 20, 2024 (JP) 2024-139175

(51) Int. Cl. H10B 43/35; H10B 43/10; H10B 43/40; H10D 30/01; H10D 30/69; H10D 62/10; H10D 64/01

(52) U.S. Cl. CPC H10B 43/35; H10B 43/40; H10D 30/0413; H10D 30/696; H10D 62/102; H10D 64/037; H10B 43/10

(57) ABSTRACT

A NOR flash memory that suppresses leakage current of non-selected cells and is compatible with a NAND flash memory is provided. The NOR flash memory includes an active region, formed within a silicon substrate extending along a bit line direction; a trench, adjacent to the active region; a charge storage layer, formed on the active region corresponding to each memory cell; a sidewall insulator, formed within the trench and formed on a sidewall of the active region; a first conductive layer, formed on the charge storage layer for each memory cell; a first conductive layer formed on the charge storage layer corresponding to each memory cell; and a second conductive layer, formed on the first conductive layer extending along a word line direction. The second conductive layer is electrically connected to the first conductive layer and contacts the sidewall insulator within the trench.

### CROSS-REFERENCE TO RELATED APPLICATION

This application claims the priority benefit of Japan Application No. 2024-074328, filed on May 1, 2024, Japan Application No. 2024-077743, filed on May 13, 2024, and Japan Application No. 2024-139175, filed on Aug. 20, 2024. The entirety of each of the above-mentioned patent applications is hereby incorporated by reference herein and made a part of this specification.

### BACKGROUND

### Technical Field

The disclosure relates to a non-volatile semiconductor storage device, and in particular to a NOR flash memory with a two-dimensional structure.

### Description of Related Art

In a Not OR (NOR) flash memory, a floating gate (FG) having excellent charge retention characteristics is adopted in a cell structure. The floating gate includes, for example, polysilicon. For example, Japanese Patent Application Laid-Open No. 2006-339207 discloses a NOR flash memory that reduces power supply voltage without deteriorating operating speed through enabling an overlapping region between a floating gate and a drain layer to be narrower than an overlapping region between the floating gate and a source layer.

In a conventional NOR flash memory of the FG type, due to the miniaturization, there are issues such as increased leakage current between a bit line and a source line in a non-selected cell during reading and writing, such that normal operations cannot be performed, and the gate length cannot be formed below 45 nm. Therefore, the cell area cannot be reduced.

In addition, when a chip is required to include the NOR flash memory capable of high-speed access and a Not AND (NAND) flash memory with a large storage capacity, the compatibility of cell array structures or manufacturing processes of the two must be considered.

### SUMMARY

The disclosure provides a NOR flash memory, which suppresses leakage current of a non-selected cell and is compatible with a NAND flash memory, and a manufacturing method thereof.

A NOR flash memory of the disclosure includes an active region, formed by extending along a bit line direction within a semiconductor substrate; a trench, adjacent to the active region; a charge storage layer, formed on the active region corresponding to each memory cell and including a nitride layer sandwiched between insulating layers; a sidewall insulator, formed within the trench and formed on a sidewall of the active region; a first conductive layer, formed on the charge storage layer corresponding to each memory cell; and a second conductive layer, extending along a word line direction and formed on the first conductive layer. The second conductive layer is electrically connected to the first conductive layer and contacts the sidewall insulator within the trench.

In an embodiment, the memory cell includes a memory cell transistor formed on a surface side of the active region and a sidewall transistor formed on a side surface side of the active region. In an embodiment, a source/drain region adjacent to a channel region of the memory cell transistor is formed on a surface of the active region, and a source/drain region adjacent to a channel region of the sidewall transistor is formed on a side surface of the active region. In an embodiment, the trench is aligned with sidewalls of the first conductive layer and the charge storage layer. In an embodiment, the charge storage layer includes an oxide-nitride-oxide (ONO) structure, a stacked structure of multiple insulating films other than oxide is included between a silicon substrate and the nitride layer, or a stacked structure of multiple insulating films other than oxide is included between the nitride and the first conductive layer. In an embodiment, the memory cell transistor and the sidewall transistor are connected in parallel, and multiple memory cells are connected in series between a bit line side select transistor and a source line side select transistor. In an embodiment, the bit line side select transistor is electrically connected to a bit line, and the source line side select transistor is electrically connected to a source line. In an embodiment, the trench is formed in a self-aligned manner when etching the first conductive layer, the charge storage layer, and the semiconductor substrate.

A manufacturing method of a NOR flash memory of the disclosure includes the following steps. A stack of a charge storage layer including a nitride layer sandwiched between insulating layers and a first conductive layer is formed on a semiconductor substrate. The first conductive layer, the charge storage layer, and the semiconductor substrate are simultaneously etched, the first conductive layer and the charge storage layer are patterned along a bit line direction, and a trench for defining an active region is formed on the semiconductor substrate. A sidewall insulator covering sidewalls of the charge storage layer, the first conductive layer, and the active region is formed. A second conductive layer extending along a word line direction in a manner of covering the sidewall insulator and the first conductive layer is formed. A doped region for source/drain is formed on a surface and a side surface of the active region not covered by the second conductive layer.

In an embodiment, the manufacturing method further includes the following steps. The second conductive layer is conformally formed on the semiconductor substrate including the first conductive layer. The second conductive layer, the first conductive layer, and the charge storage layer are simultaneously etched, and the second conductive layer, the first conductive layer, and the charge storage layer are patterned along the word line direction. In an embodiment, the manufacturing method further includes filling the trench with an insulator. A surface of the insulator is lower than the surface of the active region, and a bottom of the sidewall insulator is connected to the insulator. In an embodiment, the manufacturing method further includes the following steps. A mask pattern covering a cell array region is formed, and the charge storage layer and the first conductive layer in a peripheral region are removed. A gate insulating film and a gate material separated from the charge storage layer and the first conductive layer are formed in the peripheral region. In an embodiment, the step of forming the gate insulating film and the gate material includes conformally forming the gate insulating film and the gate material on the semiconductor substrate, and planarizing the gate insulating film and the gate material until the first conductive layer in the cell array region is exposed.

According to the disclosure, the charge storage layer including the nitride layer is formed for each memory cell. Therefore, compared with an FG type memory cell, leakage current between the bit line and the source line may be suppressed in the non-selected cell, capacitive coupling between adjacent memory cells may be reduced, and the threshold distribution of the memory cell may be narrowed. In addition, through aligning the trench adjacent to the active region with the sidewalls of the charge storage layer and the first conductive layer, the capacitive coupling between the adjacent memory cells may be reduced while implementing high integration of a cell array.

### BRIEF DESCRIPTION OF THE DRAWINGS

FIG. 1 is a plan diagram of a cell array of a NOR flash memory with a two-dimensional structure according to an embodiment of the disclosure.

FIG. 2A is a cross-sectional diagram taken along a line A-A of FIG. 1, and FIG. 2B is a cross-sectional diagram taken along a line B-B of FIG. 1.

FIG. 3A is an equivalent circuit of a cell array shown in FIG. 1, FIG. 3B is an equivalent circuit of a memory cell, and FIG. 3C is a cross-sectional diagram of a memory cell.

FIG. 4A to FIG. 4C are schematic diagrams of a manufacturing process of a cell array of a NOR flash memory according to an embodiment of the disclosure.

FIG. 5A to FIG. 5C are schematic diagrams of a manufacturing process of a cell array of a NOR flash memory according to an embodiment of the disclosure.

FIG. 6A to FIG. 6D are schematic diagrams of a manufacturing process of a cell array of a NOR flash memory according to an embodiment of the disclosure.

FIG. 7A is a plan diagram of a substrate when etching a first control gate, a charge storage layer, and the substrate through a mask pattern M1, FIG. 7B is a plan diagram of the substrate after removing the mask pattern M1, and FIG. 7C is a plan diagram of the substrate after forming a mask pattern M2.

FIG. 8A to FIG. 8D are schematic diagrams of a manufacturing process of a cell array region and a peripheral region of a NOR flash memory according to an embodiment of the disclosure.

FIG. 8E and FIG. 8F are schematic diagrams of another manufacturing process of a cell array region and a peripheral region of a NOR flash memory according to an embodiment of the disclosure.

FIG. 9A to FIG. 9C are schematic diagrams of a manufacturing process of a cell array region and a peripheral region of a NOR flash memory according to an embodiment of the disclosure.

FIG. 10A and FIG. 10B are schematic diagrams of a manufacturing process of a cell array region and a peripheral region of a NOR flash memory according to an embodiment of the disclosure.

FIG. 11 is a threshold distribution diagram of a memory cell.

FIG. 12 is a diagram of a part of a cell array during a program operation.

### DESCRIPTION OF THE EMBODIMENTS

A NOR flash memory with a two-dimensional structure of the disclosure uses silicon nitride (SiN) as a charge storage layer, such as a silicon-oxide-nitride-oxide-silicon (SONOS)-type charge storage layer to implement narrowing of a threshold distribution (Vth) of a memory cell. In addition, the NOR flash memory of the disclosure is used as a storage medium in various semiconductor devices (for example, a microcontroller, a microprocessor, a logic device, etc. in which such a flash memory is embedded).

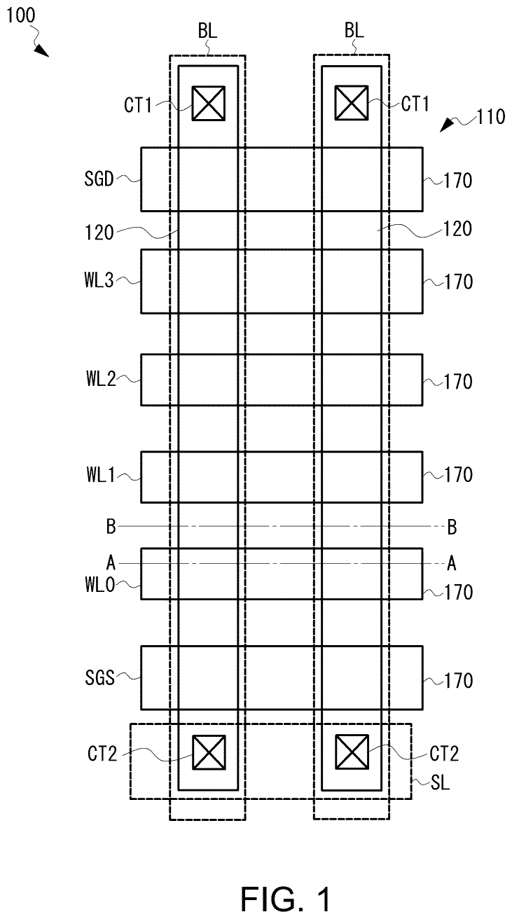

Refer to FIG. 1. In a NOR flash memory 100 of the embodiment, for example, multiple active regions 120 extending along a bit line direction are formed on a P-type semiconductor substrate 110, and each of the active regions 120 is isolated by a trench 130.

Multiple memory cells are formed between a bit line side select transistor connected to an SGD gate line and a source line side select transistor connected to an SGS gate line. A bit line BL is electrically connected to a drain region of the bit line side select transistor via a connector CT1, and a common source line SL is commonly connected to a source of the source line side select transistor via a connector CT2. Here, as an example, four word lines WL0 to WL3 are disposed between the bit line side select transistor and the source line side select transistor, and each of the word lines WL0 to WL3 is commonly connected to a gate of the corresponding memory cell in a row direction. Such a cell array structure is similar to a cell array structure of a NAND flash memory, and therefore is compatible.

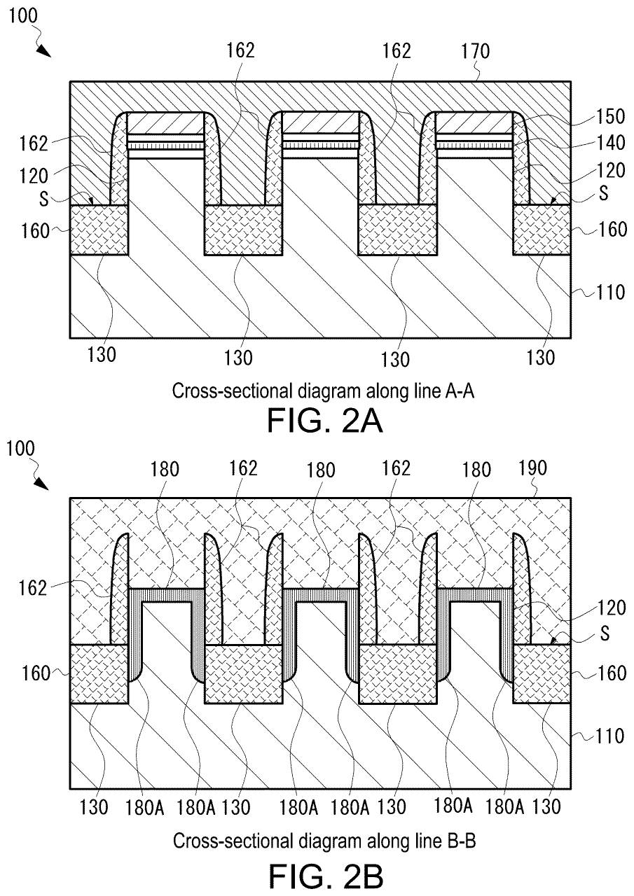

FIG. 2A is a cross-sectional diagram taken along a line A-A of a region of a memory cell. As shown in FIG. 2A, the active region 120 formed on the semiconductor substrate 110 provides a channel region for a memory cell, and a patterned charge storage layer 140 is formed in the active region 120 of each memory cell. The charge storage layer 140 includes an oxide-nitride-oxide (ONO) structure and may store charges at an interface of nitride. Alternatively, the charge storage layer 140 may also be formed by stacking multiple insulating films instead of a single oxide layer between a silicon substrate and a nitride layer or multiple insulating films instead of a single oxide layer between nitride and a gate. A patterned first control gate (CG1) 150 is formed above the charge storage layer 140 corresponding to each memory cell. The first control gate 150 includes, for example, doped conductive polysilicon or may be formed by stacking multiple low-resistance materials, such as TaN or other metal layers.

A trench insulator 160 is formed to fill the trench 130. An outermost surface S of the trench insulator 160 is lower than an outermost surface of the active region 120. In addition, a sidewall insulator 162 is formed to cover sidewalls of the first control gate 150 and the charge storage layer 140. A bottom of the sidewall insulator 162 is connected to the trench insulator 160.

An outermost surface of the first control gate 150 is exposed by the sidewall insulator 162, and a second control gate 170 extending along a word line direction is formed on the first control gate 150. The second control gate 170 is electrically connected to the first control gate 150 directly thereunder, and the second control gate 170 and the first control gate 150 together form each of the word lines WL0 to WL3. The second control gate 170 is ideally low-resistance and includes, for example, a metal material such as Al or Cu. In addition, the first control gate 150 may include the same or different material as the second control gate 170.

Although not shown here, similarly for the bit line side select transistor and the source line side select transistor, the second control gate 170 and the first control gate 150 together form the SGD gate line and the SGS gate line respectively, and the second control gate 170 is electrically connected to the first control gate 150 of the bit line side select transistor and the source line side select transistor respectively.

FIG. 2B is a cross-sectional diagram taken along a line B-B of a region where a memory cell is not formed. An N-type diffusion region 180 for a memory cell is formed on a surface of the active region 120 adjacent to the channel region of the memory cell, that is, the surface of the active region 120 exposed by the word line. Furthermore, N-type diffusion regions 180A are formed at a certain depth on two opposite sides of the active region 120, and the diffusion regions 180A are connected to the diffusion region 180 on the surface.

Different from the region of the memory cell, the charge storage layer 140 and the first control gate 150 are not formed in the active region 120, the trench insulator 160 fills the trench 130, and the sidewall insulator 162 protrudes from the active region 120. In addition, the second control gate 170 is not formed, and instead, an interlayer insulating film 190 is formed to cover the trench insulator 160, the sidewall insulator 162, and the active region 120.

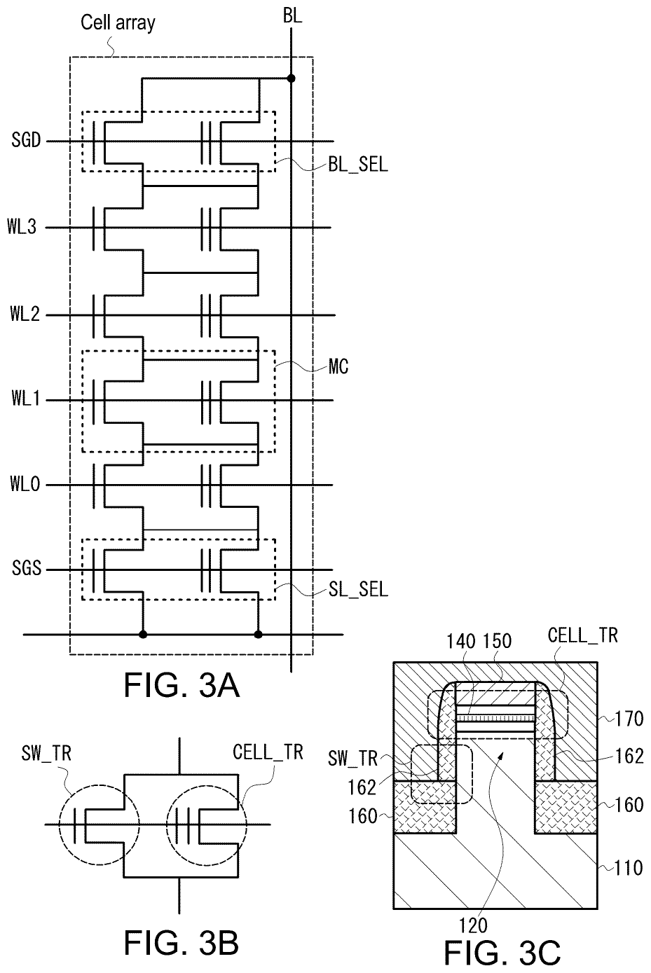

FIG. 3A is an equivalent circuit of a cell array of FIG. 1, FIG. 3B is an equivalent circuit of a memory cell, and FIG. 3C is a cross-sectional diagram of a memory cell. As shown in the figures, two or more memory cells MC (four memory cells are exemplified in the figures) are connected between a bit line side select transistor BL_SEL and a source line side select transistor SL_SEL. One memory cell MC includes a memory cell transistor CELL_TR and a sidewall transistor SW_TR connected in parallel, and the four memory cells MC are connected in series.

The memory cell transistor CELL_TR includes the channel region of the outermost surface of the active region 120, the charge storage layer 140 and the first control gate 150 on the active region 120, and the N-type diffusion region 180 serving as a source/drain. On the other hand, the sidewall transistor SW_TR includes the channel region of a side surface of the active region 120, the sidewall insulator 162 serving as a gate insulating film, and the N-type diffusion region 180A serving as a source/drain. A threshold of the sidewall transistor SW_TR is adjusted through the film thickness of the sidewall insulator 162 or the concentration of boron of the channel region.

As described above, in the NOR flash memory 100 of the embodiment, the charge storage layer 140 has an oxide-nitride-oxide (ONO) structure. The ONO structure provides a SONOS structure formed between the semiconductor substrate 110 (the silicon substrate or a silicon well) and the first control gate 150 containing polysilicon. During a program operation, the charge storage layer 140 stores charges Fowler-Nordheim (FN) tunneled through the oxide layer from the channel region on an interface of the nitride layer. During an erase operation, the charges stored in the charge storage layer FN tunnel through the oxide layer to be released to the channel region.

In the embodiment, the film thickness of the nitride layer (the SiN layer) of the charge storage layer 140 is relatively less than that of a floating gate of an FG structure, and the nitride layer is an insulating film. Therefore, compared with the FG structure, capacitive coupling between adjacent memory cells may be reduced. As a result, the narrowing of the threshold distribution of the memory cell may be implemented. Furthermore, the cell array structure of the NOR flash memory 100 of the embodiment has a structure of multiple memory cells connected in series between the bit line side select transistor and the source line side select transistor. Therefore, in the case where the NAND flash memory is formed on the same chip, a manufacturing process may be simplified through a compatible manufacturing process.

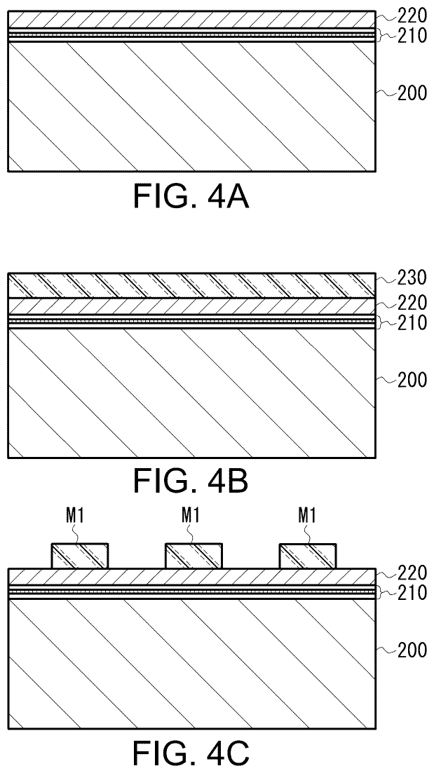

Next, a manufacturing process of a cell array of the NOR flash memory of the embodiment will be described with reference to FIG. 4A to FIG. 7C. As shown in FIG. 4A, a charge storage layer 210 having a three-layer structure composed of an oxide film such as SiO₂, a SiN film such as Si₃N₄, and an oxide film such as SiO₂ is formed on a surface of a P-type silicon substrate or P-type well 200 (hereinafter referred to as substrate for convenience) through chemical vapor deposition (CVD), etc. In addition, a first control gate 220 made of, for example, polysilicon is formed on the charge storage layer 210.

Next, as shown in FIG. 4B, a mask material 230 such as an etch resist is, for example, formed. Next, the mask material 230 is patterned through a lithography process, as shown in FIG. 4C, to form mask patterns M1 spaced at specific intervals and extending along the bit line direction.

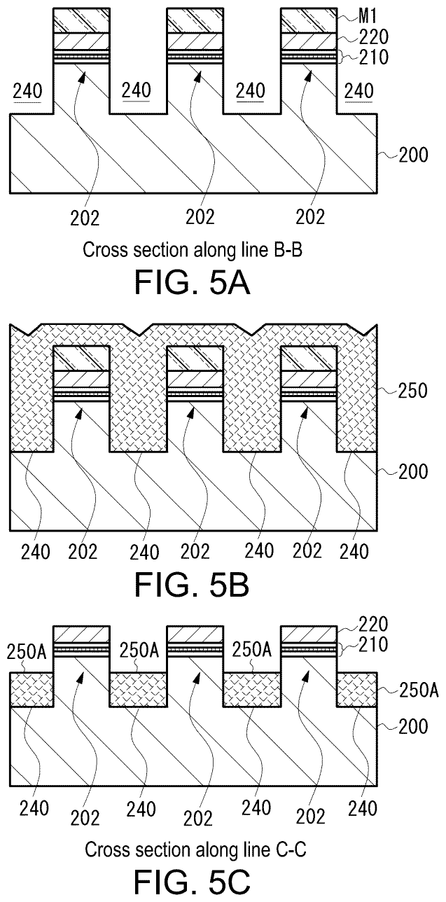

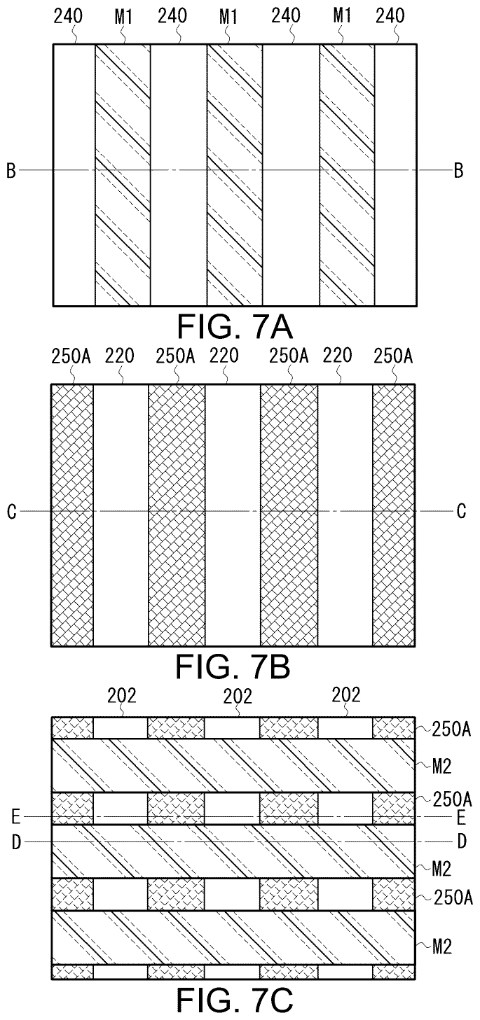

Next, as shown in FIG. 5A, the exposed first control gate 220, charge storage layer 210, and substrate 200 are simultaneously anisotropically etched through the mask patterns M1, and a stack of the patterned charge storage layer 210 and first control gate 220 is formed on the substrate 200. While patterning, a trench 240 for defining an active region 202 is formed within the substrate 200. FIG. 7A is a plan diagram of a substrate when the first control gate 220, the charge storage layer 210, and the substrate 200 are etched through the mask patterns M1, and FIG. 5A corresponds to a cross section taken along a line B-B of FIG. 7A.

When the stack of the charge storage layer 210 and the first control gate 220 is etched, and the trench 240 is formed by self-aligning with the stack of the charge storage layer 210 and the first control gate 220. Therefore, the trench 240 is formed with high accuracy without positional error between the stack of the charge storage layer 210 and the first control gate 220. In addition, the charge storage layer 210 is covered by the first control gate 220 and is thus protected from being etched.

Next, as shown in FIG. 5B, an insulating film 250 is conformally formed on the substrate 200 including the trench 240. Then, the insulating film 250 is etched, so that a trench insulator 250A is retained within the trench 240. At this time, the mask patterns M1 protect the first control gate 220 from being etched.

Next, as shown in FIG. 5C, the mask patterns M1 are removed. An outermost surface of the trench insulator 250A within the trench 240 is located below an outermost surface of the active region 202. Thus, the active region 202 extending along the bit line direction is isolated by the trench insulator 250A, and the stack of the charge storage layer 210 and the first control gate 220 is formed in the active region 202. FIG. 7B is a plan diagram of a substrate after the mask pattern M1 is removed, and FIG. 5C corresponds to a cross section taken along a line C-C of FIG. 7B.

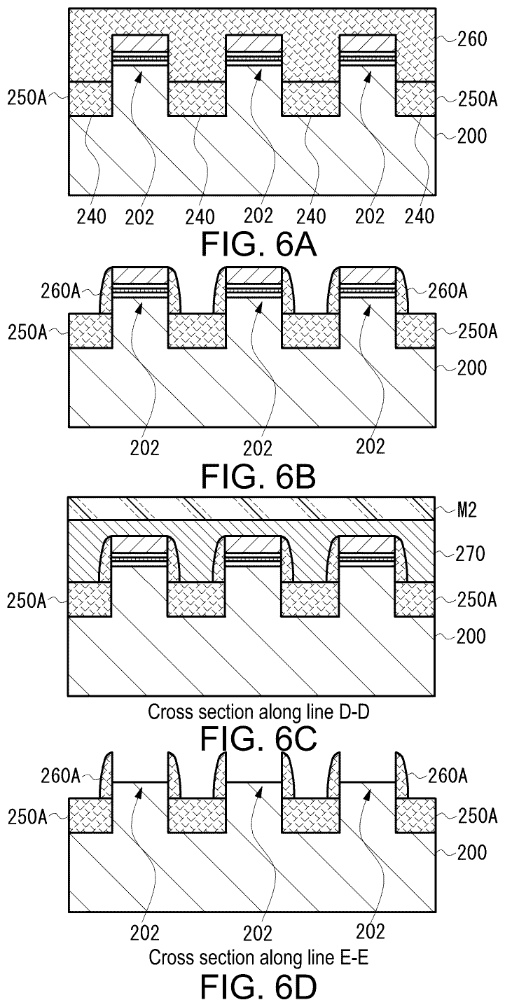

Next, as shown in FIG. 6A, an insulating film 260 is conformally formed on the substrate, and the insulating film 260 is anisotropically etched, thereby forming a sidewall insulating film 260A covering sidewalls of the charge storage layer 210 and the first control gate 220, as shown in FIG. 6B. The sidewall insulating film 260A is connected to the trench insulator 250A at the bottom.

Next, as shown in FIG. 6C, a conductive material 270 is conformally formed on the substrate, and a mask pattern M2 extending along the word line direction is formed thereon. FIG. 7C is a plan diagram of a substrate after the mask pattern M2 is formed, and FIG. 6C corresponds to a cross section taken along a line D-D of FIG. 7C. The conductive material 270 is etched through the mask pattern M2 to pattern the second control gate extending along the word line direction. At this time, in a region where the memory cell is not formed, as shown in FIG. 6D, the exposed conductive material 270, first control gate 220, and charge storage layer 210 are simultaneously etched through the mask pattern M2 to expose the active region 202.

Next, phosphorus or arsenic is ion-implanted into the exposed active region 202, as shown in FIG. 2B, to form the N-type diffusion regions 180 and 180A on the surface and the side surface of the active region 202. Next, an insulating film is conformally formed on the substrate including the second control gate, and the insulating film is planarized through, for example, chemical mechanical polishing (CMP) until a surface of the second control gate is exposed.

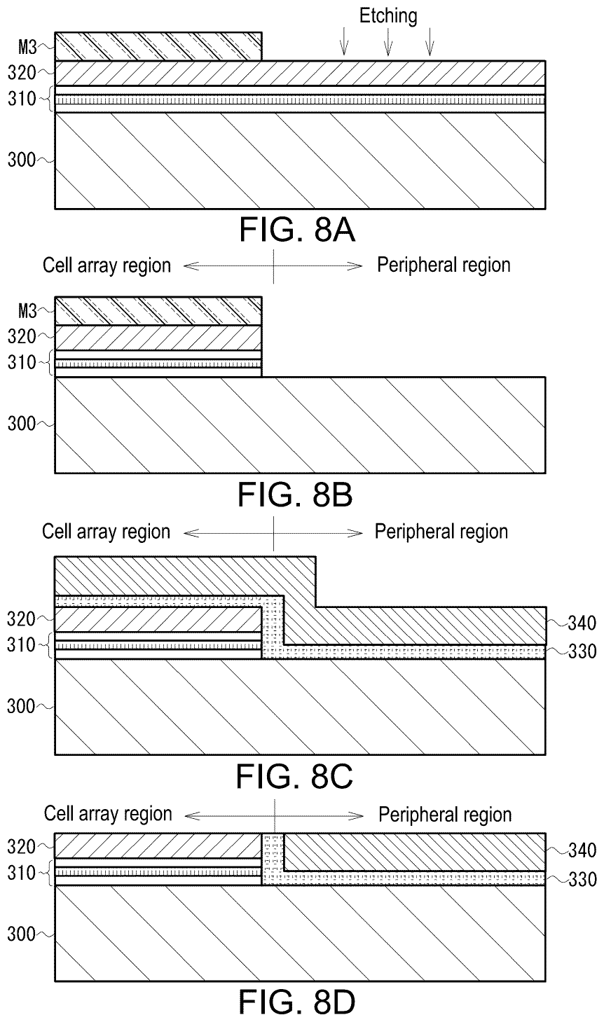

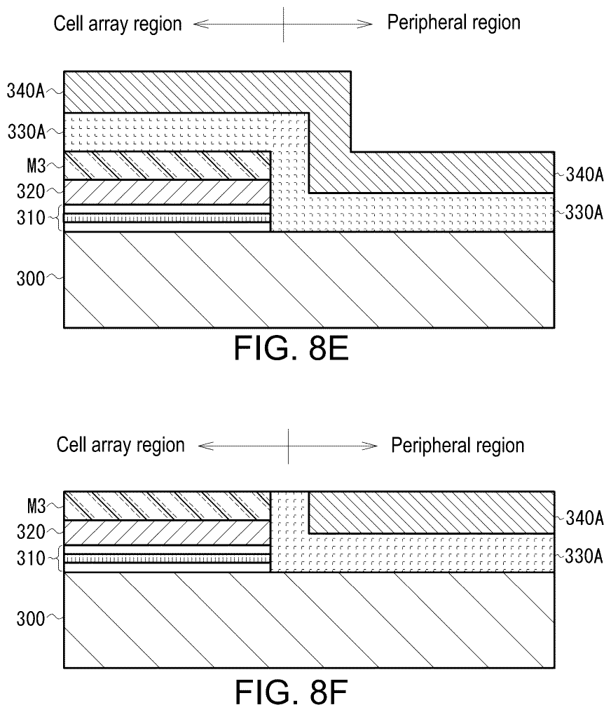

Next, a manufacturing processes of a cell array region and a peripheral region of the NOR flash memory of the embodiment will be described with reference to FIG. 8A to FIG. 10B. As shown in FIG. 8A, a charge storage layer 310 and a first control gate (CG1) 320 are conformally formed on a P-type silicon substrate 300. Then, a mask pattern M3 covering the cell array region is formed. Next, as shown in FIG. 8B, the charge storage layer 310 and the first control gate 320 in the peripheral region are removed through etching using the mask pattern M3 as an etch mask.

After removing the mask pattern M3, as shown in FIG. 8C, a gate insulating film 330 is conformally formed on the substrate 300 including the peripheral region. The gate insulating film 330 is, for example, silicon oxide. A sense amplifier, a decoder, etc. is formed in the peripheral region, and the circuits include transistors driven by high voltage or transistors driven by low voltage. Therefore, the gate insulating film 330 may be formed with various film thicknesses, such as a thick film suitable for high voltage and a thin film suitable for low voltage. After the gate insulating film 330 is formed, a gate material 340 for the transistor in the peripheral region is conformally formed on the substrate 300. The gate material 340 is, for example, polysilicon.

Next, the gate insulating film 330 and the gate material 340 are etched back or planarized, as shown in FIG. 8D, so that the first control gate 320 is exposed in the cell array region and the gate material 340 is exposed in the peripheral region. Via the manufacturing processes, the charge storage layer 310 and the first control gate 320 in the cell array region and the gate insulating film 330 and the gate material 340 in the peripheral region may be respectively formed.

During the manufacturing process, after the mask pattern M3 is removed, the gate insulating film 330 and the gate material 340 are formed, but just as an example, and the mask pattern M3 may also be retained. As shown in FIG. 8E, a gate insulating film 330A and a gate material 340A are conformally formed on the substrate including the mask pattern M3. In this case, in the case where the gate insulating film 330A in the peripheral region is a thick insulating film with a high withstand voltage, the height of the mask pattern M3 in the cell array region is substantially the same as the height of the gate material 340A. In addition, the gate insulating film 330A at a boundary between the cell array region and the peripheral region is a thick insulating film with a high withstand voltage.

Next, as shown in FIG. 8F, a planarization process is performed to expose the mask pattern M3 in the cell array region and the gate material 340A in the peripheral region, and the mask pattern M3 is removed. Via the manufacturing processes, the charge storage layer 310 and the first control gate 320 in the cell array region and the gate insulating film 330A and the gate material 340A in the peripheral region may be separately formed.

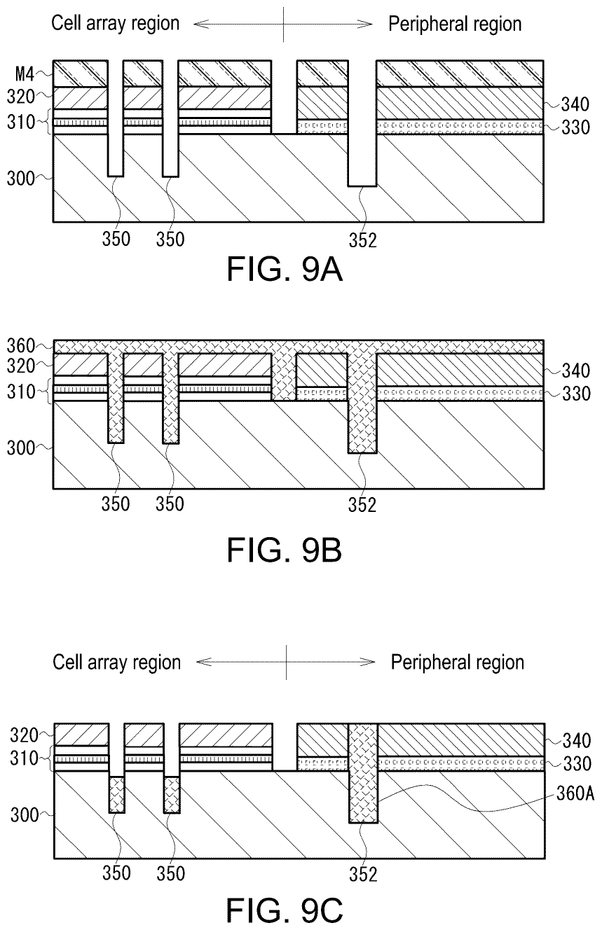

After the first control gate 320 in the cell array region and the gate material 340 in the peripheral region are respectively formed, a mask pattern M4 as shown in FIG. 9A is formed, and the gate material, the gate insulating film, and silicon in the cell array region and the peripheral region are simultaneously etched to form a trench 350 and a trench 352 on the substrate 300. The trench 350 formed in the cell array region may have a different size and/or a different depth from the trench 352 formed in the peripheral region.

After removing the mask pattern M4, as shown in FIG. 9B, an insulating material 360 is formed to fill the trench 350 and the trench 352. The insulating material 360 is, for example, silicon oxide. Next, as shown in FIG. 9C, the insulating material 360 is etched to form a trench insulator 360A in the trench 350 and the trench 352. Furthermore, in the peripheral region, the trench insulator 360A filling the trench 352 is etched to the same height as the gate material 340 and is not etched to a deeper depth.

Next, as described in FIG. 6A and FIG. 6B, a sidewall insulating film (not shown here) is formed to cover sidewalls of the active region 202, the charge storage layer 310, and the first control gate 320.

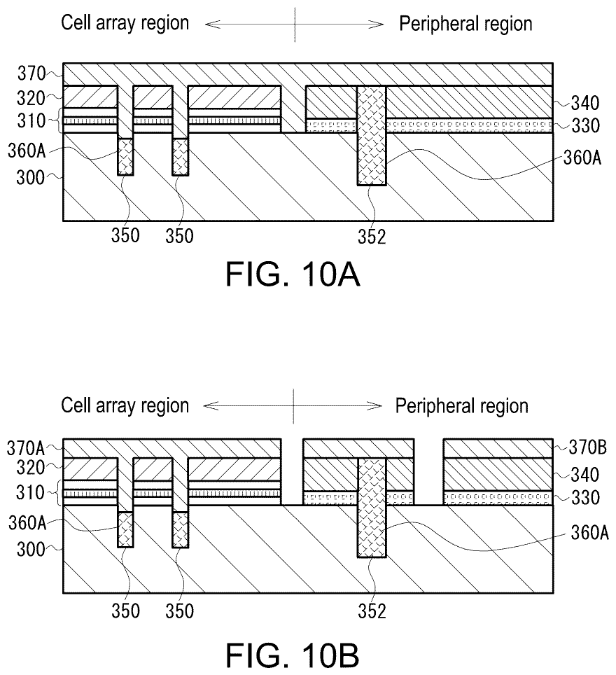

Next, as shown in FIG. 10A, a conductive material 370 serving as a precursor of the second control gate is conformally formed on the substrate 300 including the first control gate 320 and the gate material 340. The conductive material 370 is not particularly limited and may be, for example, a metal material such as Al or Cu. The conductive material 370 is electrically connected to the first control gate 320 and the gate material 340. In addition, metal silicide may be formed between the conductive material 370 and the first control gate 320 and the gate material 340.

Next, through an unshown mask pattern, as shown in FIG. 10B, the conductive material 370 in a region where the charge storage layer 310 and the first control gate 320 are formed within the cell array is patterned to extend along the word line direction, thereby forming a second control gate 370A. The second control gate 370A is electrically connected to the corresponding first control gates 320 in the row direction and provides a word line (see FIG. 6C for details). In addition, through patterning the conductive material 370, the first control gate 320 and the charge storage layer 310 located thereunder are simultaneously etched to expose the active region (see FIG. 6D for details). On the other hand, through patterning the conductive material 370, a wiring layer 370B electrically connected to the gate material 340, etc. is formed in the peripheral region.

After the second control gate 370A is patterned, ion implantation is performed in the exposed active region 202 to form an N-type doped region for source/drain. Furthermore, similarly to the conventional NAND flash memory, the bit line BL and the source line SL are formed in the cell array region.

The two-dimensional NOR flash memory of the embodiment has the charge storage layer formed by stacking the insulating layers including SiN between silicon and the control gate. The control gate is composed of two layers, that is, the first control gate formed on the charge storage layer and the second control gate formed on the first control gate. Through sequentially depositing the charge storage layer and the first control gate on silicon, the first control gate, the charge storage layer, and silicon may be simultaneously etched to form a trench isolation region self-aligned with the first control gate and the charge storage layer. Afterwards, the second control gate is formed on the first control gate, and the first control gate and the second control gate are electrically connected to each other to form the word line. An end portion of the word line in the cell array region is connected to a row decoder, and the row decoder applies a bias voltage for a read/write (program/erase) operation to a word line WL.

Next, the operation of the NOR flash memory of the embodiment is described. The NOR flash memory of the embodiment is shown in the equivalent circuit of the cell array of FIG. 3A. One memory cell includes the memory cell transistor CELL_TR and the sidewall transistor SW_TR. The memory cell transistor CELL_TR includes the charge storage layer 140 formed on the surface of the active region and the first control gate 150 and the second control gate 170 serving as gates. The sidewall transistor SW_TR includes the sidewall insulator formed on the side surface of the active region and the second control gate 170 serving as a gate filled within the trench.

The charge storage layer of the memory cell transistor CELL_TR stores charges through programming. Therefore, a threshold voltage (Vt) of the memory cell transistor changes according to the charges within the charge storage layer. The bit line side select transistor BL_SEL and the source line side select transistor SL_SEL also include two transistors (that is, the memory cell transistor CELL_TR and the sidewall transistor SW_TR). However, the transistors are not suitable for the program operation or the erase operation. Therefore, the charge storage layer has no charge or a fixed charge, and the threshold voltage is maintained at a constant value. Therefore, the threshold Vt of the source line side select transistor SL_SEL is determined by the lower threshold Vt of the two transistors. The threshold Vt of the bit line side select transistor BL_SEL is also determined by the lower threshold Vt.

Among the memory cells, the memory cells connected to one word line may be referred to as a page, and the memory cells within multiple pages sandwiched between SGS and SGD may be referred to as a block, which are similar to the cell array of the NAND flash memory.

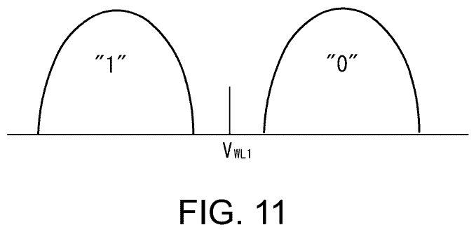

Next, the read operation of the NOR flash memory of the embodiment is described. FIG. 11 shows the threshold Vt distribution of the memory cell transistor CELL_TR when the NOR flash memory stores one bit in each memory cell. V_{WL1} is a voltage applied to the word line WL of the selected memory cell during reading. The threshold Vt distribution of the sidewall transistor SW_TR must be higher than the voltage V_{WL1} of the selected word line.

The threshold Vt of a cell “1” is set to be lower than V_{WL1}. In the case where the threshold Vt of the memory cell transistor CELL_TR is lower than V_{WL1}, the selected memory cell transistor CELL_TR is in a conducted state and the sidewall transistor SW_TR is in a disconnected state. The threshold Vt of a cell “0” is set to be higher than V_{WL1}. In the case where the threshold Vt of the memory cell transistor CELL_TR is higher than V_{WL1}, the selected memory cell transistor CELL_TR is in a disconnected state and the sidewall transistor SW_TR is in a disconnected state.

Table 1 shows the bias voltage of each component during the read operation. Cells of one page within the selected block may be simultaneously read. In order to correctly read the selected cell, a voltage V_{WL2} is applied to a non-selected word line. Here, V_{WL2} is set to be higher than the threshold Vt of the sidewall transistor SW_TR. Therefore, all the sidewall transistors SW_TR connected to the non-selected word lines are in a conducted state, that is, regardless of the threshold Vt of the memory cell transistor CELL_TR, all the non-selected memory cells are in a conducted state, and the sidewall transistor SW_TR of the selected memory cell is in a disconnected state, so that data of the selected memory cell transistor CELL_TR may be correctly read. During the read operation, a voltage higher than the thresholds Vt of the source line side select transistor SL_SEL and the bit line side select transistor BL_SEL is applied to an SGS gate and an SGD gate, so that the select transistors are in a conducted state.

TABLE 1
Read

| | Bias voltage | |
|---|---|---|
| V_{BL} | 0.5~1.5 | V |
| V_{SL} | 0 | V |
| V_{P-WELL} | 0 | V |
| Selected block | | |
| V_{WL} (selected WL) | V_{WL1} = 0~2 V | |
| V_{WL} (non-selected WL) | V_{WL2} = 1~3 V > V_{WL1} | |
| V_{SGS} | 1~3 | V |
| V_{SGD} | 1~3 | V |
| Non-selected block | | |
| V_{WL} | 0 | V |
| V_{SGS} | 0 | V |
| V_{SGD} | 0 | V |

For example, in FIG. 3A, when data of the memory cell MC connected to the word line WL1 is read, the sidewall transistor SW_TR connected to the word line WL1 is in a disconnected state, and the sidewall transistors SW_TR connected to the non-selected word lines WL0, WL2, and WL3 are all in a conducted state. According to data “0” or “1” held in the memory cell transistor CELL_TR connected to the word line WL1, current flows from the bit line BL to the source line SL and is read by the sense amplifier.

During reading, in a non-selected cell array (non-selected block), V_{WL}, V_{SGS}, and V_{SGD} are grounded. That is, the word line WL, the SGS gate, and the SGD gate of the non-selected cell array are grounded during reading. In order to prevent read errors of the non-selected cell array, the thresholds Vt of the source line side select transistor and the bit line side select transistor must be higher than 0 V. As a result, the non-selected cell array may be completely in a disconnected state. Therefore, when a positive bias voltage is applied to the bit line BL, and a source line and a P-well are grounded, in the case where the read cell of the selected block is a “1” cell, current flows from the bit line BL to the source line SL, and current does not flow from the bit line BL to the source line SL in the non-selected block.

In the NOR flash memory of the embodiment, similar to the NAND structure, the cell array structure also has a structure in which the memory cell is connected between the source line side select transistor and the bit line side select transistor. Therefore, leakage current between the bit line and the source line of the non-selected block may be suppressed as much as possible through the source line side select transistor and the bit line side select transistor with relatively long gate lengths. Therefore, the gate length of the memory cell itself may be shortened, which may reduce the effective cell size to miniaturize the area of the memory cell.

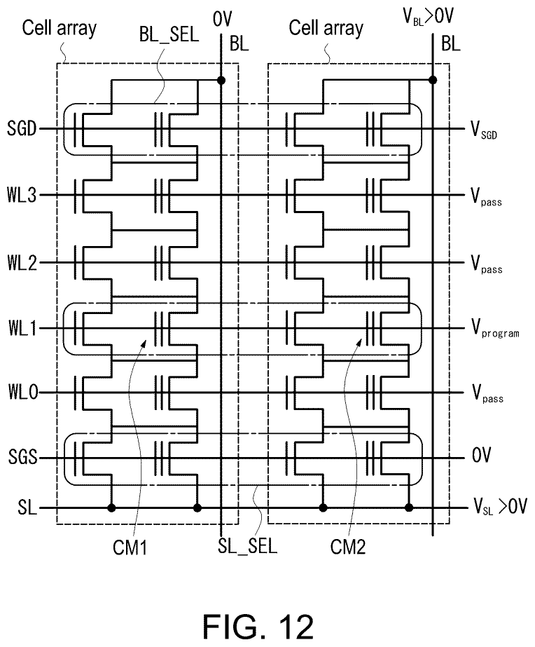

Table 2 shows the bias voltage during programming. During the program operation, the cells within one page may be programmed at a time. FIG. 12 shows two NOR cell arrays surrounded by dotted lines and shows an example in which “0” is programmed in a cell CM1 connected to the word line WL1 and “1” is programmed (that is, programming of “0” is prohibited) in a cell CM2.

TABLE 2
Program

| | Bias voltage | |
|---|---|---|
| V_{BL} (program “0”) | 0 | V |
| V_{BL} (program “1”) | 1.2~3 | V |
| V_{P-WELL} | 0 | V |
| V_{SL} | 1~2 | V |
| Selected block | | |
| V_{WL} (selected WL) | V_{program} = 8~16 V | |
| V_{WL} (non-selected WL) | Vₚₐₛₛ = V_{program}/2 | |
| V_{SGS} | 0 | V |
| V_{SGD} | 1~2 | V |
| Non-selected block | | |
| V_{WL} | 0 | V |
| V_{SGS} | 0 | V |
| V_{SGD} | 0 | V |

0 V is applied to the bit line BL of the cell array on the left, and a positive voltage (V_{BL}=1.2 V to 3 V) is applied to the bit line BL of the cell array on the right. A high voltage (V_{program}=8 V to 16 V) is applied to the selected word line WL to be programmed, and a voltage approximately half of V_{program} (Vₚₐₛₛ=4 V to 8 V) is applied to other word lines WL within the same cell array. A positive bias voltage (V_{SGD}=1 V to 2 V) is applied to the SGD gate, but must be higher than the threshold Vt of the bit line side select transistor BL_SEL. 0 V is applied to the SGS gate, a positive bias voltage (V_{SL}=1 V to 2 V) is applied to the source line SL, and the P-well is grounded.

Through applying 0 V to the bit line BL on the left and applying the positive bias voltage to the SGD gate, the bit line side select transistor BL_SEL is in a conducted state and the source side of the source line side select transistor SL_SEL is grounded. Through applying Vₚₐₛₛ to the non-selected cell, the non-selected cell is also in a conducted state, and 0 V is supplied to the channel region of the selected cell (the cell CM1 on the left connected to WL1). Through grounding the channel and applying the high voltage (V_{program}) to the word line WL1, electrons may be tunneled to the charge storage layer. Therefore, the threshold Vt of the cell CM1 increases, and the cell CM1 is programmed to a “0” state.

On the other hand, a positive bias voltage is applied to the bit line BL on the right, so the bit line side select transistor BL_SEL is in a disconnected state. Through applying 0 V to the SGS gate, the source line side select transistor SL_SEL is in a disconnected state. Therefore, the channel of the NOR cell array on the right is separated from the bit line BL and the source line SL. Afterwards, through applying Vₚₐₛₛ and V_{program} to the non-selected word line WL and the selected word line WL1, the channel region of the NOR cell array on the right may be increased. As a result, a voltage difference between the silicon surface and the word line WL is reduced, tunneling of electrons from the silicon surface to the charge storage layer disappears, and the threshold Vt of the cell CM2 does not shift. Therefore, the selected cell CM2 is programmed to “1”. The program sequence is basically the same as the programming of the conventional NAND flash memory.

In addition, during the program operation, V_{WL}, V_{SGS} and V_{SGD} of the non-selected blocks are grounded, and the non-selected blocks may be completely in a disconnected state through the source line side select transistor and the bit line side select transistor with relatively long gate lengths. Therefore, the gate length of the memory cell itself may be shortened, which may reduce the effective cell size.

Next, the erase operation will be described. Table 3 shows the bias voltage during the erase operation. In the NOR flash memory of the disclosure, one block may be erased at a time. Through grounding all the word lines WL of the selected block and applying Vₑᵣₐₛₑ (8 V to 16 V) to the P-well, electrons within the charge storage layer move to the silicon surface or electron holes on the silicon surface tunnel into the charge storage layer. Thus, the threshold Vt of the cell shifts to a low value, and the cell is in a “1” state. The bit line BL, the source line SL, the SGS gate line, the SGD gate line, and the word line WL of the non-selected block are in a floating state. The word line WL is in a floating state, and V_{WL} is automatically increased to a magnitude close to VP-WELL, so the threshold Vt of the cell of the non-selected block does not shift.

TABLE 3
Erase

| | Bias voltage |
|---|---|
| V_{BL} | Floating |
| V_{SL} | Floating |
| V_{P-WELL} | Vₑᵣₐₛₑ = 8~16 V |
| Selected block | |
| V_{WL} (selected WL) | 0 V |
| V_{SGS} | Floating |
| V_{SGD} | Floating |
| Non-selected block | |
| V_{WL} | Floating |
| V_{SGS} | Floating |
| V_{SGD} | Floating |

In addition, the thickness of the sidewall insulating film (thickness of oxide (Tox): effective oxide film thickness) serving as the gate insulating film of the sidewall transistor depends on V_{program} or Verase. In order to prevent insulation breakdown of the sidewall insulating film, an electric field applied between the second control gate and the sidewall of silicon (the active region) needs to be below 5 MV/cm (V_{program}/Tox≤5 MV/cm, and Vₑᵣₐₛₑ/Tox≤5 MV/cm).

As described above, the NOR flash memory of the embodiment accumulates charges in the charge storage layer in which the insulating layers including nitride are stacked. In addition, the memory cell includes the sidewall transistor including the sidewall insulator formed on the trench sidewall and the second control gate within the trench, and the memory cell transistor including the charge storage layer formed on the silicon surface side, the first control gate, and the second control gate. The source and the drain are formed in a space between the two cells, and ion implantation of the source and the drain is performed on a surface and a sidewall of silicon (the active region).

In the embodiment, the charge storage layer composed of the three-layer structure of oxide-nitride-oxide is shown, but the disclosure is not limited thereto, and the charge storage layer having four or more layers including nitride may also be used. In addition, the memory cell May be a single level cell (SLC) storing 1 bit (binary data) or may be other types storing multiple bits.

Although the preferred embodiments of the disclosure have been described in detail, the disclosure is not limited to the specific embodiments, and various modifications and changes may be made within the scope of the disclosure described in the claims.

What is claimed is:

1. A NOR flash memory, comprising:
an active region, formed by extending along a bit line direction within a semiconductor substrate;
a trench, adjacent to the active region;
a charge storage layer, formed in the active region corresponding to each memory cell and comprising a nitride layer sandwiched between insulating layers;
a sidewall insulator, formed within the trench and formed on a sidewall of the active region;
a first conductive layer, formed on the charge storage layer corresponding to each memory cell; and
a second conductive layer, extending along a word line direction and formed on the first conductive layer,
wherein the second conductive layer is electrically connected to the first conductive layer and contacts the sidewall insulator within the trench.

2. The NOR flash memory according to claim 1, wherein the memory cell comprises a memory cell transistor formed on a surface side of the active region and a sidewall transistor formed on a side surface side of the active region.

3. The NOR flash memory according to claim 2, wherein a source/drain region adjacent to a channel region of the memory cell transistor is formed on a surface of the active region, and a source/drain region adjacent to a channel region of the sidewall transistor is formed on a side surface of the active region.

4. The NOR flash memory according to claim 1, wherein the trench is aligned with sidewalls of the first conductive layer and the charge storage layer.

5. The NOR flash memory according to claim 1, wherein the charge storage layer comprises an oxide-nitride-oxide structure.

6. The NOR flash memory according to claim 1, wherein a stacked structure of a plurality of insulating films other than oxide is comprised between a silicon substrate and the nitride layer.

7. The NOR flash memory according to claim 1, wherein a stacked structure of a plurality of insulating films other than oxide is comprised between the nitride and the first conductive layer.

8. The NOR flash memory according to claim 2, wherein the memory cell transistor and the sidewall transistor are connected in parallel,
a plurality of memory cells are connected in series between a bit line side select transistor and a source line side select transistor.

9. The NOR flash memory according to claim 8, wherein the bit line side select transistor is electrically connected to a bit line, and the source line side select transistor is electrically connected to a source line.

10. The NOR flash memory according to claim 1, wherein the trench is formed in a self-aligned manner when etching the first conductive layer, the charge storage layer, and the semiconductor substrate.

11. A manufacturing method of a NOR flash memory, comprising:
forming a stack of a charge storage layer comprising a nitride layer sandwiched between insulating layers and a first conductive layer on a semiconductor substrate;
simultaneously etching the first conductive layer, the charge storage layer, and the semiconductor substrate, patterning the first conductive layer and the charge storage layer along a bit line direction, and forming a trench for defining an active region on the semiconductor substrate;
forming a sidewall insulator covering sidewalls of the charge storage layer, the first conductive layer, and the active region;
forming a second conductive layer extending along a word line direction in a manner of covering the sidewall insulator and the first conductive layer; and
forming a doped region for source/drain on a surface and a side surface of the active region not covered by the second conductive layer.

12. The manufacturing method of the NOR flash memory according to claim 11, further comprising:
conformally forming the second conductive layer on a semiconductor substrate comprising the first conductive layer; and
simultaneously etching the second conductive layer, the first conductive layer, and the charge storage layer, and patterning the second conductive layer, the first conductive layer, and the charge storage layer along the word line direction.

13. The manufacturing method of the NOR flash memory according to claim 11, further comprising: filling the trench with an insulator, wherein a surface of the insulator is lower than the surface of the active region, and a bottom of the sidewall insulator is connected to the insulator.

14. The manufacturing method of the NOR flash memory according to claim 12, further comprising:
forming a mask pattern covering a cell array region, and removing the charge storage layer and the first conductive layer in a peripheral region; and
forming a gate insulating film and a gate material separated from the charge storage layer and the first conductive layer in the peripheral region.

15. The manufacturing method of the NOR flash memory according to claim 14, wherein the step of forming the gate insulating film and the gate material comprises:
conformally forming the gate insulating film and the gate material on the semiconductor substrate, and planarizing the gate insulating film and the gate material until the first conductive layer in the cell array region is exposed.

16. The manufacturing method of the NOR flash memory according to claim 12, wherein the charge storage layer comprises an oxide-nitride-oxide structure.

17. The manufacturing method of the NOR flash memory according to claim 12, wherein a stacked structure of a plurality of insulating films other than oxide is comprised between a silicon substrate and the nitride layer.

18. The manufacturing method of the NOR flash memory according to claim 12, wherein a stacked structure of a plurality of insulating films other than oxide is comprised between the nitride and the first conductive layer.
